(19) United States
(12) Patent Application Publication
(10) Pub. No.: US 2025/0336882 A1
(43) Pub. Date: Oct. 30, 2025

(54) SUBSTRATE ALIGNMENT METHOD

(71) Applicant: Samsung Electronics Co., Ltd., Suwon-si (KR)

(72) Inventors: Jaeho HONG, Suwon-si (KR); TAEHONG MIN, Suwon-si (KR); Sangjun PARK, Suwon-si (KR); TAE-HOI PARK, Suwon-si (KR); SANG-HO YUN, Suwon-si (KR)

(21) Appl. No.: 18/919,737

(22) Filed: Oct. 18, 2024

(30) Foreign Application Priority Data
Apr. 25, 2024 (KR) 10-2024-0055237

(51) Int. Cl. H01L 23/00; G06V 10/143; G06V 10/145; G06V 10/147

(52) U.S. Cl. CPC H01L 24/80; G06V 10/143; G06V 10/145; G06V 10/147; G06V 2201/06; H01L 2224/8013; H01L 2224/80894

(57) ABSTRACT

A substrate alignment method includes inserting a first substrate and a second substrate into a substrate bonding apparatus, causing an imaging unit to recognize at least one alignment key, aligning the first substrate and the second substrate by using the at least one alignment key recognized by the imaging unit, and performing a bonding of the first substrate and the second substrate after confirming that the alignment is completed. The imaging unit includes an imaging housing, a plurality of light sources on an upper side of an interior of the imaging housing, an optical lens below the plurality of light sources, a polarizing plate downwardly spaced apart from the optical lens, and a reading module configured to read information about a position of the alignment key. The plurality of light sources includes two visible light sources, a near-infrared light source, and a far-infrared light source.

### CROSS-REFERENCE TO RELATED APPLICATION

This U.S. nonprovisional application claims priority under 35 U.S.C § 119 to Korean Patent Application No. 10-2024-0055237 filed on Apr. 25, 2024 in the Korean Intellectual Property Office, the disclosure of which is hereby incorporated by reference in its entirety.

### BACKGROUND

The present inventive concepts relate to a substrate alignment method, and more particularly, to a substrate alignment method which improves camera performance to accurately recognize alignment keys.

In fabricating a semiconductor device, a direct bonding process may be performed to bond two or more substrates to each other. The substrate bonding process may be executed to increase a mounting density of semiconductor chips in a semiconductor device. For example, a semiconductor module having a structure in which semiconductor chips are stacked may be advantageous in reducing a wiring length between semiconductor chips and in providing high-speed signal processing together with the increase in mounting density of semiconductor chips. When a semiconductor module is fabricated in the structure of a stacked semiconductor chip, productivity may be increased in a process where wafers are bonded and then cut into stacked semiconductor chips, compared to a case where semiconductor chips are bonded after being cut. The substrate bonding process may be performed in a wafer-to-wafer manner where two wafers are directly bonded without a separate medium therebetween. Before wafers are bonded, two wafers may be aligned with each other. An alignment key may be engraved on the wafer. An image of the alignment key engraved on the wafer may be captured, for example, by a camera, to align the two wafers with each other.

### SUMMARY

Some embodiments of the present inventive concepts provide a substrate alignment method capable of increasing alignment accuracy of substrates that are bonded to each other.

The object of the present inventive concepts is not limited to the mentioned above, and other objects which have not been mentioned above will be clearly understood to those skilled in the art from the following description.

According to some embodiments of the present inventive concepts, a substrate alignment method may comprise: inserting a first substrate and a second substrate into a substrate bonding apparatus; causing an imaging unit to recognize at least one alignment key; aligning the first substrate and the second substrate by using the at least one alignment key recognized by the imaging unit; and performing a bonding of the first substrate and the second substrate after confirming that the alignment of the first substrate and the second substrate is completed, wherein the imaging unit includes: an imaging housing; a plurality of light sources on an upper side of an interior of the imaging housing; an optical lens below the plurality of light sources; a polarizing plate beneath and spaced apart from the optical lens; and a reading module configured to read information about a position of the alignment key, wherein the plurality of light sources include: two visible light sources; a near-infrared light source; and a far-infrared light source.

According to some embodiments of the present inventive concepts, a substrate alignment method may comprise: inserting a first substrate and a second substrate into a substrate bonding apparatus; causing an imaging unit to recognize a first alignment key on the first substrate and a second alignment key on the second substrate; aligning the first substrate and the second substrate by using the first alignment key and the second alignment key recognized by the imaging unit; and performing a bonding of the first substrate and the second substrate after confirming that the alignment of the first substrate and the second substrate is completed, wherein the imaging unit includes: an imaging housing; a plurality of light sources on an upper side of an interior of the imaging housing; an optical lens beneath and spaced apart from the plurality of light sources; a polarizing plate beneath and spaced apart from the optical lens; and a reading module configured to read information about a position of the first alignment key and the second alignment key.

According to some embodiments of the present inventive concepts, a substrate alignment method may comprise: inserting and loading a first substrate and a second substrate into a substrate bonding apparatus; causing an imaging unit to recognize a first alignment key on the first substrate and a second alignment key on the second substrate; aligning the first substrate and the second substrate by using the first alignment key and the second alignment key recognized by the imaging unit; and performing a bonding of the first substrate and the second substrate after confirming that the alignment of the first substrate and the second substrate is completed, wherein the imaging unit includes: an imaging housing; a plurality of light sources on an upper side of an interior of the imaging housing; and an optical lens beneath and spaced apart from the plurality of light sources, wherein the plurality of light sources include: two visible light sources; a near-infrared light source; and a far-infrared light source, wherein the substrate bonding apparatus includes: a bonding chamber; a lower chuck which is combined with a lower chuck driver in the bonding chamber and on which the first substrate is disposed; and an upper chuck which is combined with an upper chuck driver on an upper side of an interior of the bonding chamber and on which the second substrate is disposed.

According to some embodiments of the present inventive concepts, a substrate bonding apparatus may comprise: a chamber; a lower chuck in the chamber, the lower chuck configured to support a first substrate; an upper chuck in the chamber, the upper chuck configured to support a second substrate; a camera configured to capture an image of an alignment key positioned on at least one of the first substrate and the second substrate; and a controller configured to move at least one of the lower chuck and the upper chuck to align the first substrate and the second substrate based on the image of the alignment key captured by the camera, wherein the camera includes a plurality of light sources configured to irradiate light having different wavelengths from each other.

Details of other example embodiments are included in the description and drawings.

### BRIEF DESCRIPTION OF DRAWINGS

FIG. 1 illustrates a cross-sectional view showing a substrate bonding apparatus according to some embodiments of the present inventive concepts.

FIG. 2 illustrates a simplified schematic diagram showing an imaging unit according to some embodiments of the present inventive concepts.

FIG. 3 illustrates a flow chart showing a substrate alignment method according to some embodiments of the present inventive concepts.

FIGS. 4 to 8 illustrate diagrams showing a substrate alignment method according to the flow chart of FIG. 3.

FIG. 9 illustrates a diagram showing an alignment key captured by an imaging unit.

FIG. 10 illustrates a graph showing the degree of contrast of light when a substrate alignment is performed according to the flow chart of FIG. 3.

### DETAILED DESCRIPTION OF EMBODIMENTS

The following will now describe some embodiments of the present inventive concepts with reference to the accompanying drawings. Like reference numerals may indicate like components throughout the description.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

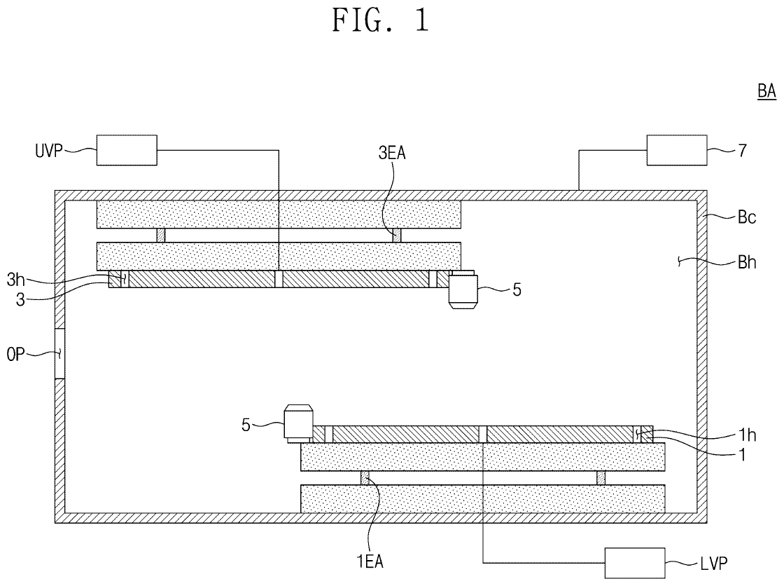

FIG. 1 illustrates a cross-sectional view showing a substrate bonding apparatus according to some embodiments of the present inventive concepts.

Referring to FIG. 1, a substrate bonding apparatus BA may be provided. The substrate bonding apparatus BA may be a system configured to directly bond two substrates to each other. For example, the substrate bonding apparatus BA may be an apparatus for a direct bonding process. A substrate bonded by the direct bonding process may be a wafer-level substrate. For example, the substrate bonding apparatus BA may bond two wafers to each other. The present inventive concepts, however, are not limited thereto, and the substrate bonding apparatus BA may be used to bond a chip to a wafer or a chip to another chip. The substrate bonding apparatus BA may include a bonding chamber Bc, a lower chuck 1, an upper chuck 3, an imaging unit 5 (e.g., a camera or a plurality of cameras), a lower chuck driver 1EA, an upper chuck driver 3EA, a lower vacuum pump LVP, an upper vacuum pump UVP, and a controller 7.

Although not illustrated, the controller 7 may include one or more of the following components: at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the controller 7 (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the controller 7 may include antennas, network interfaces that provide wireless and/or wire line digital and/or analog interface to one or more networks over one or more network connections (not shown), a power source that provides an appropriate alternating current (AC) or direct current (DC) to power one or more components of the controller, and a bus that allows communication among the various disclosed components of the controller.

The bonding chamber Bc may include a bonding space Bh. A bonding between two substrates may be achieved in the bonding space Bh. A vacuum pressure or atmospheric pressure may be formed in the bonding space Bh. The bonding chamber Bc may include an opening Op. A substrate may be loaded or unloaded through the opening Op into or from the bonding space Bh. The opening Op may be closed or sealed as needed. For example, the opening Op may be closed or sealed to divide the bonding space Bh from an outward environment.

The lower chuck 1 may support a substrate. The lower chuck 1 may include a lower vacuum hole 1h. The lower vacuum hole 1h may be connected to the lower vacuum pump LVP. The lower vacuum pump LVP may provide a vacuum pressure to the lower vacuum hole 1h, and the vacuum pressure may rigidly hold a substrate on the lower chuck 1. The lower vacuum hole 1h may be provided in plural. The plurality of lower vacuum holes 1h may be spaced apart from each other in a horizontal direction. However, unless otherwise specially stated, a single lower vacuum hole 1h will be discussed in the following description.

The upper chuck 3 may support a substrate. The upper chuck 3 may be upwardly spaced apart from the lower chuck 1. For example, the upper chuck 3 and the lower chuck 1 may be disposed to face each other. The upper chuck 3 may include an upper vacuum hole 3h. The upper vacuum hole 3h may be connected to the upper vacuum pump UVP. The upper vacuum pump UVP may provide a vacuum pressure to the upper vacuum hole 3h, and the vacuum pressure may rigidly hold a substrate on a bottom surface of the upper chuck 3. The upper vacuum hole 3h may be provided in plural. The plurality of upper vacuum holes 3h may be spaced apart from each other in a horizontal direction. However, unless otherwise specially stated, a single upper vacuum hole 3h will be discussed in the following description.

The imaging unit 5 may be disposed at an end of each of the lower chuck 1 and the upper chuck 3. For example, a first imaging unit 5 may be disposed at an end of the lower chuck 1 and a second imaging unit 5 may be disposed at an end of the upper chuck 3. The imaging unit 5 may capture an image of a top surface of a substrate. For example, the imaging unit 5 may capture an alignment key engraved on a top surface of a substrate. The imaging unit 5 disposed at the end of the lower chuck 1 may capture an image of a substrate supported by the upper chuck 3. In addition, the imaging unit 5 disposed at the end of the upper chuck 3 may capture an image of a substrate supported by the lower chuck 1. The imaging unit 5 will be further discussed in detail below.

The lower chuck driver 1EA may drive the lower chuck 1 to move. For example, the lower chuck driver 1EA may operate while connected to the lower chuck 1. The lower chuck driver 1EA may drive the lower chuck 1 to move upwards and downwards. For example, the lower chuck driver 1EA may include a motor and/or an actuator.

The upper chuck driver 3EA may drive the upper chuck 3 to move. For example, the upper chuck driver 3EA may operate while connected to the upper chuck 3. The upper chuck driver 3EA may drive the upper chuck 3 to move upwards and downwards. For example, the upper chuck driver 3EA may include a motor and/or an actuator.

The lower vacuum pump LVP may be connected to the lower vacuum hole 1h. The lower vacuum pump LVP may provide the lower vacuum hole 1h with a vacuum pressure. A vacuum pressure provided from the lower vacuum pump LVP may force the lower chuck 1 to support a substrate.

The upper vacuum pump UVP may be connected to the upper vacuum hole 3h. The upper vacuum pump UVP may provide the upper vacuum hole 3h with a vacuum pressure. A vacuum pressure provided from the upper vacuum pump UVP may force the upper chuck 3 to support a substrate.

The controller 7 may be communicatively connected to the bonding chamber Bc. The controller 7 may control an overall operation of the substrate bonding apparatus BA. For example, the controller 7 may cause the lower chuck 1 and the upper chuck 3 to move. For example, the controller 7 may control the lower chuck driver 1EA and the upper chuck driver 3EA to operate. In addition, the controller 7 may receive an alignment error value calculated based on an image of an alignment key captured by the imaging unit 5. Thus, the controller 7 may drive the lower chuck 1 and the upper chuck 3 to correct the alignment error value. For example, the controller 7 may bond a substrate whose alignment error value is corrected.

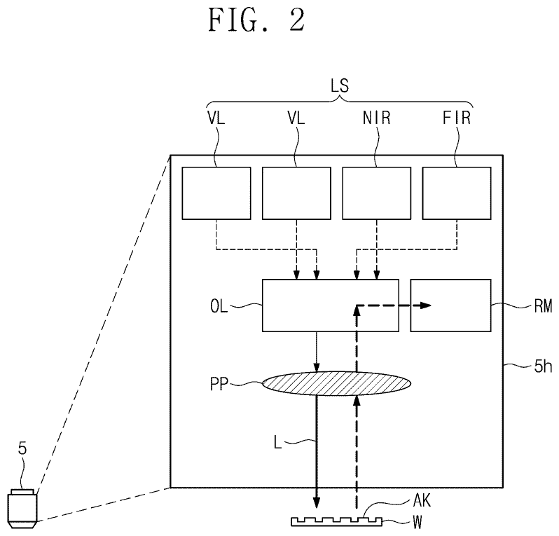

FIG. 2 illustrates a simplified schematic diagram showing a capturing section (e.g., an imaging unit 5) according to some embodiments of the present inventive concepts.

Referring to FIG. 2, the imaging unit 5 may include an imaging housing 5h, a plurality of light sources LS, an optical lens OL, a polarizing plate PP, and a reading module RM.

The imaging housing 5h may include a condensing space. The condensing space in the imaging housing 5h may generate and condense light. The plurality of light sources LS, the optical lens OL, and the polarizing plate PP may be disposed in the condensing space.

The plurality of light sources LS may be positioned on an upper side of an interior of the imaging housing 5h. Four light sources LS may be provided. For example, the plurality of light sources LS may include two visible light source VL, a near-infrared light source NIR, and a far-infrared light source FIR.

The two visible light sources VL may irradiate a light corresponding to the visible light. The visible light may indicate a light having a range of electromagnetic waves that can be seen by the human eye. The light irradiated from the two visible light sources VL may have a wavelength of about 620 nm to about 750 nm. The two visible light sources VL may provide a red light and/or a white light. For example, a first visible light source VL may irradiate a red light and a second visible light source VL may irradiate a white light. The two visible light sources VL may irradiate the light to the optical lens OL.

The near-infrared light source NIR may irradiate a light corresponding to the near-infrared light. The near-infrared light may indicate a light having a wavelength range in the infrared light, which is relatively close to the visible light. For example, light irradiated from the near-infrared light source NIR may have a wavelength of about 780 nm. The near-infrared light source NIR may irradiate the light to the optical lens OL.

The far-infrared light source FIR may irradiate a light corresponding to far-infrared light. The far-infrared light may indicate a light having the longest wavelength in the infrared light. For example, light irradiated from the far-infrared light source FIR may have a wavelength of about 850 nm. The far-infrared light source FIR may irradiate the light to the optical lens OL.

The optical lens OL may be positioned below the plurality of light sources LS. The optical lens OL may control the light. For example, the optical lens OL may have an optical power that causes incident light to diverge. In addition, the optical lens OL may be transparent to the light irradiated from the plurality of light sources LS. For example, the optical lens OL may allow the passage of the light incident from the plurality of light sources LS, thereby increasing an angle made with an optical axis.

The polarizing plate PP may be disposed downwardly spaced apart from the optical lens OL. The polarizing plate PP may polarize the light that has passed through the optical lens OL. For example, the polarizing plate PP may allow the passage of the light whose angle is increased while passing through the optical lens OL, and the light may thus be transformed into light having a single polarization direction. A spot diameter of the light that has passed through the polarizing plate PP may be larger than a spot diameter of the light that has passed through the optical lens OL. For example, the polarization plate PP may have an optical power such that divergent light traveling between the optical lens OL and the polarization plate PP may be collimated by the polarization plate PP.

The reading module RM may read information about a position of the alignment key. For example, the reading module RM may obtain an image of the alignment key captured by the imaging unit 5. In addition, an alignment error value may be calculated based on the obtained image. The reading module RM may transfer the image of the alignment key to the controller 7. The reading module RM may be disposed on one side of the interior of the imaging housing 5h. The present inventive concepts, however, are not limited thereto, and the reading module RM may be connected to an outside of the imaging housing 5h.

For example, the reading module RM may include an image sensor configured to receive light reflected by the alignment key AK. The reading module RM may further include at least one central processing unit (CPU) configured to execute computer program instructions to perform various processes and methods, random access memory (RAM) and read only memory (ROM) configured to access and store data and information and computer program instructions, input/output (I/O) devices configured to provide input and/or output to the reading module RM (e.g., keyboard, mouse, display, speakers, printers, modems, network cards, etc.), and storage media or other suitable type of memory (e.g., such as, for example, RAM, ROM, programmable read-only memory (PROM), erasable programmable read-only memory (EPROM), electrically erasable programmable read-only memory (EEPROM), magnetic disks, optical disks, floppy disks, hard disks, removable cartridges, flash drives, any type of tangible and non-transitory storage medium) where data and/or instructions can be stored. In addition, the reading module RM may include antennas, network interfaces that provide wireless and/or wire line digital and/or analog interface to one or more networks over one or more network connections (not shown), a power source that provides an appropriate alternating current (AC) or direct current (DC) to power one or more components of the reading module, and a bus that allows communication among the various disclosed components of the reading module.

For example, the reading module RM may be included in the controller 7. However, embodiments are not limited thereto, and the reading module RM may be separate and/or independent from the controller 7.

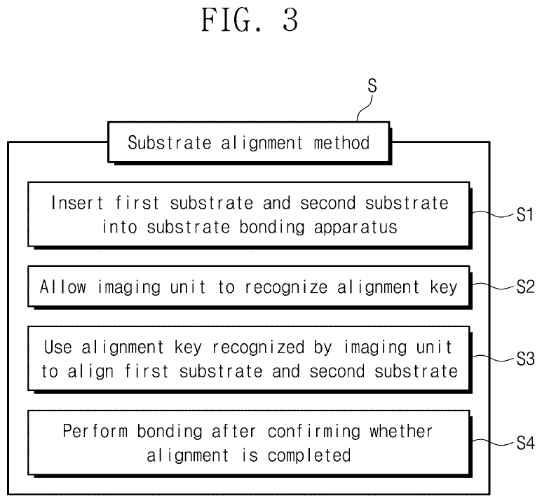

FIG. 3 illustrates a flow chart showing a substrate alignment method according to some embodiments of the present inventive concepts.

Referring to FIG. 3, a substrate alignment method S may be provided. The substrate alignment method S may include inserting a first substrate and a second substrate into a substrate bonding apparatus (S1), allowing an imaging unit to recognize an alignment key (S2), using the alignment key recognized by the imaging unit to align the first substrate and the second substrate (S3), and performing a bonding after confirming whether the alignment is completed (S4).

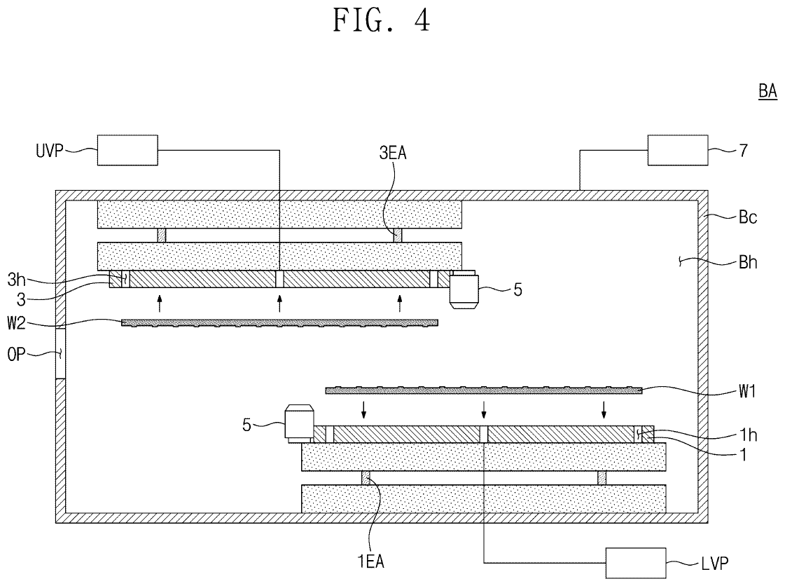

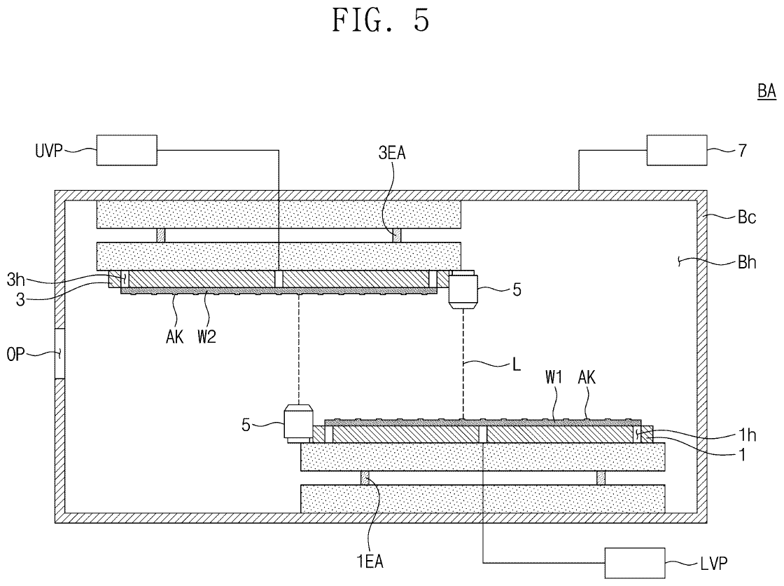

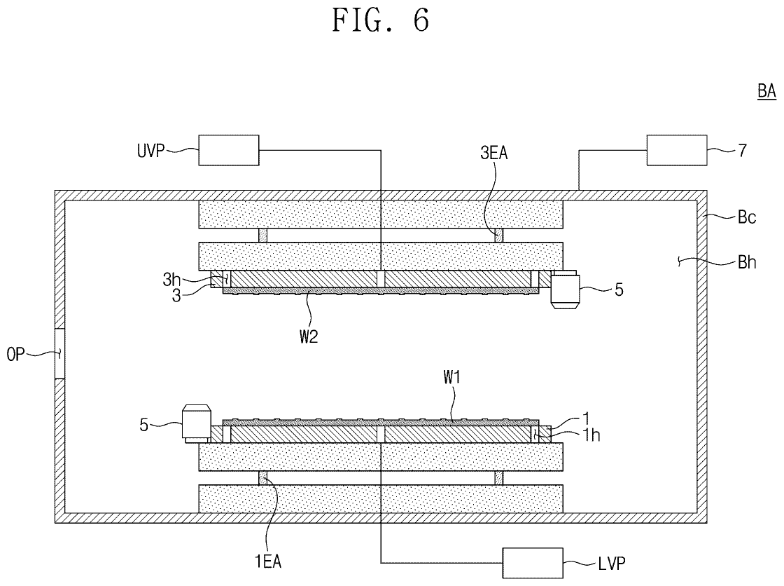

With reference to FIGS. 4 to 8, the following will provide further details regarding the substrate alignment method S of FIG. 3.

FIGS. 4 to 8 illustrate diagrams showing a substrate alignment method according to the flow chart of FIG. 3.

The insertion of the first and second substrates (S1) may include causing a first substrate W1 and a second substrate W2 to enter through the opening Op into the substrate bonding apparatus BA. A robot arm (not shown) may be used to introduce the first substrate W1 and the second substrate W2 into the bonding chamber Bc. The insertion of the first and second substrates (S1) may include placing the first substrate W1 and the second substrate W2 respectively on the lower chuck 1 and the upper chuck 3. For example, the placement of the first substrate W1 and the second substrate W2 may include adsorbing the first substrate W1 and the second substrate W2 respectively to a top surface of the lower chuck 1 and a bottom surface of the upper chuck 3. A vacuum pressure provided from the lower vacuum hole 1h may rigidly hold the first substrate W1 on the lower chuck 1. A vacuum pressure provided from the upper vacuum hole 3h may rigidly hold the second substrate W2 on the upper chuck 3.

The recognition of the alignment key (S2) may include using the plurality of light sources LS of the imaging unit 5 to irradiate light to the optical lens OL. For example, variously colored light may be irradiated from the plurality of light sources LS to the optical lens OL. A light having a relatively short wavelength may be irradiated from the two visible light sources VL among the plurality of light sources LS. Therefore, the light irradiated from the two visible light sources VL may recognize an alignment key AK present on a thin layer of either or both of the first substrate W1 and the second substrate W2. For example, a first alignment key AK may be present on the first substrate W1 and a second alignment key AK may be present on the second substrate W2. For example, the light irradiated from the two visible light sources VL may enable recognition of the alignment key positioned within a first distance (e.g., a first vertical distance) from a surface of a corresponding one of the first substrate W1 and the second substrate W2. In contrast, when the alignment key AK is positioned beyond the first distance from the surface of the first substrate W1 or the second substrate W2 (e.g., when the alignment key AK is positioned inside the first substrate W1 or the second substrate W2 away from or beneath the surface of the first substrate W1 or the second substrate W2), the imaging unit 5 may use the near-infrared light source NIR or the far-infrared light source FIR to irradiate a light to the first substrate W1 and the second substrate W2. In addition, the recognition of the alignment key (S2) may include allowing the light released from (e.g., transmitted by) the optical lens OL to become polarized while passing through the polarizing plate PP. For example, the polarization of light may include increasing contrast of light polarized by the polarizing plate PP and irradiating the light to the alignment key AK on the first substrate W1 and the second substrate W2. For example, the contrast of light polarized by the polarizing plate PP may mean the difference between the minimum and maximum intensity of the light polarized by the polarizing plate PP. For example, the polarization plate PP may have an optical power such that divergent light traveling between the optical lens OL and the polarization plate PP may be collimated by the polarization plate PP. The polarizing plate PP may allow the passage only of light having a specific polarization direction.

The recognition of the alignment key (S2) may include reflecting the light irradiated to the alignment key AK on the first substrate W1 and the second substrate W2. The reading module RM may perceive (e.g., receive) the light which has passed through the polarizing plate PP and been reflected from the alignment key AK on the first substrate W1 and the second substrate W2. For example, the reading module RM may obtain and recognize an image of the alignment key AK on the first substrate W1 and the second substrate W2. In an embodiment, the recognition of the alignment key (S2) may include performing a Fourier Transform on the light reflected to the reading module RM.

The substrate alignment (S3) may include performing an alignment by inputting the image of the alignment key AK obtained by the reading module RM into the controller 7 of the substrate bonding apparatus BA. For example, an alignment error value between the first substrate W1 and the second substrate W2 may be calculated based on an image of the alignment key AK obtained by the reading module RM. Therefore, the alignment error value may be input to the controller 7 to drive the lower chuck 1 and the upper chuck 3 to align the first substrate W1 and the second substrate W2 with each other.

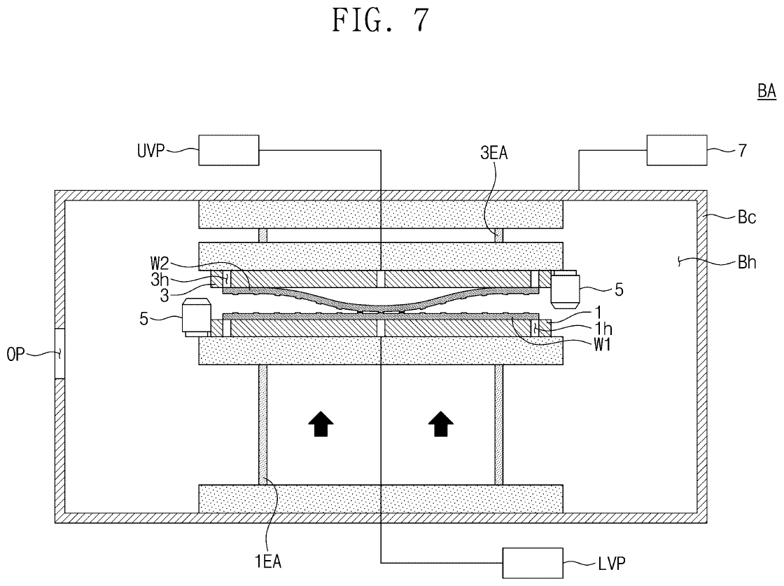

The bonding after confirming whether the alignment is completed (S4) may include causing the second substrate W2 to contact a top surface of the first substrate W1 in a state where the first substrate W1 and the second substrate W2 are aligned with each other. The contacting of substrates may include causing the lower chuck 1 and the upper chuck 3 to approach each other to force the second substrate W2 to contact the top surface of the first substrate W1. For example, the lower chuck driver 1EA may drive the lower chuck 1 to ascend to approach the upper chuck 3. In a state where the lower chuck 1 approaches the upper chuck 3, a vacuum pressure may be released from one or more of the plurality of upper vacuum holes 3h of the upper chuck 3. For example, as shown in FIG. 7, a vacuum pressure may be released from a centered one of the plurality of upper vacuum holes 3h. Thus, a central portion of the second substrate W2 may move downwards to first contact the top surface of the first substrate W1.

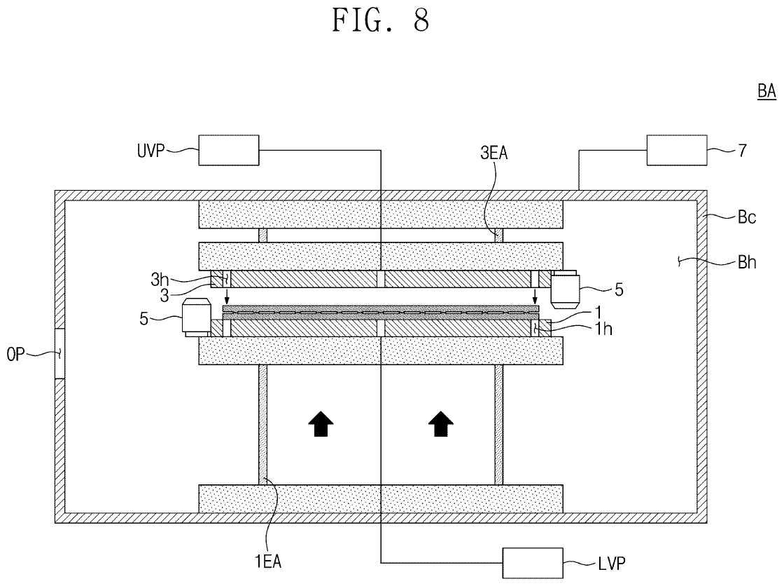

Referring to FIG. 8, a vacuum pressure may be released from remaining ones of the plurality of upper vacuum holes 3h. Thus, the second substrate W2 may be separated from the upper chuck 3 to completely contact the top surface of the first substrate W1. Accordingly, a direct bonding may be achieved between the first substrate W1 and the second substrate W2.

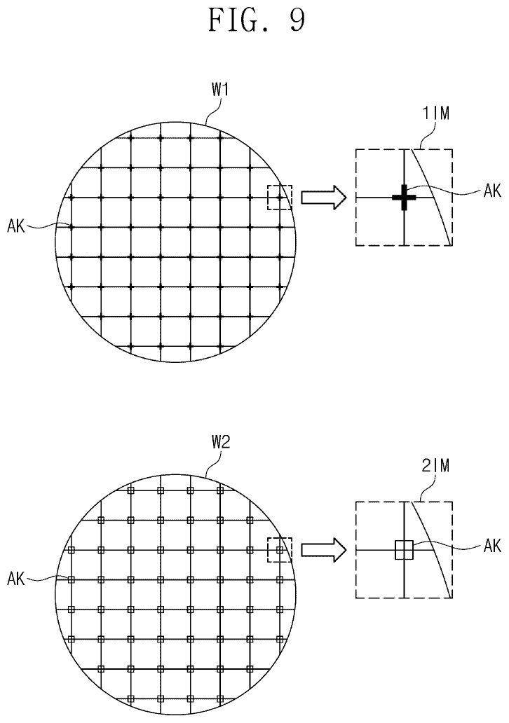

FIG. 9 illustrates a diagram showing an alignment key captured by an imaging unit.

Referring to FIG. 9, the alignment key AK may be inserted on a top surface of the first substrate W1 and a bottom surface of the second substrate W2. The alignment key AK may be disposed on every unit device that is present on the first substrate W1 and/or the second substrate W2. The present inventive concepts, however, are not limited thereto, and the alignment key AK may be limitedly disposed on only one or more unit devices. The alignment keys AK may be inserted on corresponding positions of the first and second substrates W1 and W2, such that a pair may be constituted by the alignment key AK on the first substrate W1 and the corresponding alignment key AK on the second substrate W2. The imaging unit 5 associated with the lower chuck 1 may capture the alignment key AK of the second substrate W2, thereby obtaining a first image 1IM. The imaging unit 5 associated with the upper chuck 3 may capture the alignment key AK of the first substrate W1, thereby obtaining a second image 2IM. The imaging unit 5 may transfer the first image 1IM and the second image 2IM to the reading module RM. The reading module RM may acquire the first image 1IM and the second image 2IM to obtain an alignment error value.

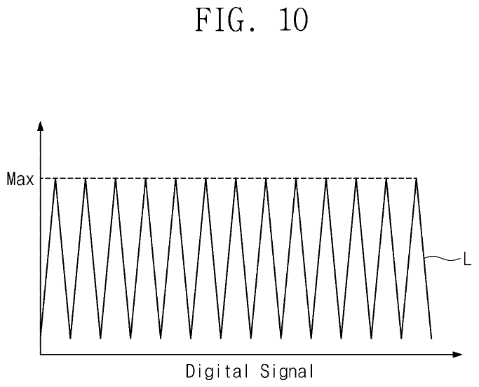

FIG. 10 illustrates a graph showing the degree of contrast of light when a substrate alignment is performed according to the flow chart of FIG. 3.

Referring to FIG. 10, a contrast may be improved when the polarizing plate PP is used to allow light to pass through. For example, the light that has passed through the polarizing plate PP may have a constant polarization direction, and thus a contrast may be improved. Accordingly, the light exiting the polarizing plate PP may be used to accurately recognize the alignment key AK inserted on a thick layer.

In a substrate alignment method according to some embodiments of the present inventive concepts, a substrate may be aligned before the substrate is directly bonded. In this stage, for the substrate alignment, an imaging unit in a substrate bonding apparatus may recognize an alignment key engraved on the substrate. Herein, performance of the imaging unit may be enhanced to accurately recognize the alignment key. For example, light sources with different color wavelengths may be equipped to recognize alignment keys on various layers. In addition, a polarizing plate may be installed to reduce noise of light, and thus the alignment keys may be clearly perceived. Performance of an imaging unit may be improved to enhance capability of recognizing the alignment keys.

According to a substrate alignment method of the present inventive concepts, performance of a camera may be improved to increase accuracy of alignment between bonded substrates.

Effects of the present inventive concepts are not limited to the mentioned above, other effects which have not been mentioned above will be clearly understood to those skilled in the art from the description provided above.

Although the present invention has been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

1. A substrate alignment method, comprising:
inserting a first substrate and a second substrate into a substrate bonding apparatus;
causing an imaging unit to recognize at least one alignment key;
aligning the first substrate and the second substrate by using the at least one alignment key recognized by the imaging unit; and
performing a bonding of the first substrate and the second substrate after confirming that the alignment of the first substrate and the second substrate is completed,
wherein the imaging unit includes:
an imaging housing;
a plurality of light sources on an upper side of an interior of the imaging housing;
an optical lens below the plurality of light sources;
a polarizing plate beneath and spaced apart from the optical lens; and
a reading module configured to read information about a position of the alignment key,
wherein the plurality of light sources include:
two visible light sources;
a near-infrared light source; and
a far-infrared light source.

2. The method of claim 1, wherein the causing of the imaging unit to recognize the at least one alignment key includes using the plurality of light sources to irradiate a light to the optical lens.

3. The method of claim 1, wherein a light exiting the optical lens becomes polarized while passing through the polarizing plate.

4. The method of claim 3, wherein the polarizing plate has an optical power such that the polarizing plate is configured to increase a contrast of the light polarized by the polarizing plate by collimating the light polarized by the polarizing plate, and
wherein the light polarized by the polarizing plate is irradiated to the at least one alignment key, wherein a first alignment key of the at least one alignment key is positioned on the first substrate and a second alignment key of the at least one alignment key is positioned on the second substrate.

5. The method of claim 1, wherein the causing of the imaging unit to recognize the at least one alignment key includes causing the reading module to receive a reflected light that has been reflected from the at least one alignment key, wherein a first alignment key of the at least one alignment key is positioned on the first substrate and a second alignment key of the at least one alignment key is positioned on the second substrate.

6. The method of claim 1, wherein a light irradiated from the two visible light sources has a wavelength of 620 nm to 750 nm.

7. The method of claim 1, wherein a light irradiated from the near-infrared light source and the far-infrared light source has a wavelength longer than a wavelength of a light irradiated from the two visible light sources.

8. The method of claim 1, wherein the two visible light sources provide a red light and a white light.

9. A substrate alignment method, comprising:
inserting a first substrate and a second substrate into a substrate bonding apparatus;
causing an imaging unit to recognize a first alignment key on the first substrate and a second alignment key on the second substrate;
aligning the first substrate and the second substrate by using the first alignment key and the second alignment key recognized by the imaging unit; and
performing a bonding of the first substrate and the second substrate after confirming that the alignment of the first substrate and the second substrate is completed,
wherein the imaging unit includes:
an imaging housing;
a plurality of light sources on an upper side of an interior of the imaging housing;
an optical lens beneath and spaced apart from the plurality of light sources;
a polarizing plate beneath and spaced apart from the optical lens; and
a reading module configured to read information about a position of the first alignment key and the second alignment key.

10. The method of claim 9, wherein the plurality of light sources include:
two visible light sources;
a near-infrared light source; and
a far-infrared light source.

11. The method of claim 10, wherein, when the first alignment key or the second alignment key is positioned at a first distance beneath a surface of the first substrate or the second substrate, the imaging unit uses the near-infrared light source or the far-infrared light source to irradiate a light to the first substrate or the second substrate.

12. The method of claim 10, wherein a light irradiated from the near-infrared light source has a wavelength of 780 nm.

13. The method of claim 10, wherein a light irradiated from the far-infrared light source has a wavelength of 850 nm.

14. The method of claim 9, wherein the aligning of the first substrate and the second substrate by using the first alignment key and the second alignment key recognized by the imaging unit includes performing an alignment by inputting information about the first alignment key and the second alignment key recognized by the reading module to a controller of the substrate bonding apparatus.

15. The method of claim 9, wherein the causing of the imaging unit to recognize the first substrate and the second substrate includes performing a Fourier Transform on a light reflected to the reading module.

16. The method of claim 9, wherein the substrate bonding apparatus includes:
a chamber;
a lower chuck on an upper side of an interior of the chamber; and
an upper chuck upwardly spaced apart from the lower chuck,
wherein the lower chuck and the upper chuck include a chuck driver.

17. The method of claim 16, wherein the inserting of the first substrate and the second substrate into the substrate bonding apparatus includes adsorbing the first substrate and the second substrate respectively on a top surface of the lower chuck and a bottom surface of the upper chuck.

18. The method of claim 16, wherein the performing of the bonding after confirming that the alignment of the first substrate and the second substrate is completed includes bonding the second substrate on the upper chuck to the first substrate on the lower chuck.

19. A substrate alignment method, comprising:
inserting and loading a first substrate and a second substrate into a substrate bonding apparatus;
causing an imaging unit to recognize a first alignment key on the first substrate and a second alignment key on the second substrate;
aligning the first substrate and the second substrate by using the first alignment key and the second alignment key recognized by the imaging unit; and
performing a bonding of the first substrate and the second substrate after confirming that the alignment of the first substrate and the second substrate is completed,
wherein the imaging unit includes:
an imaging housing;
a plurality of light sources on an upper side of an interior of the imaging housing; and
an optical lens beneath and spaced apart from the plurality of light sources, wherein the plurality of light sources include:
two visible light sources;
a near-infrared light source; and
a far-infrared light source,
wherein the substrate bonding apparatus includes:
a bonding chamber;
a lower chuck which is combined with a lower chuck driver in the bonding chamber and on which the first substrate is disposed; and
an upper chuck which is combined with an upper chuck driver on an upper side of an interior of the bonding chamber and on which the second substrate is disposed.

20. The method of claim 19, wherein the inserting and loading of the first substrate and the second substrate into the substrate bonding apparatus includes adsorbing the first substrate and the second substrate on a surface of the lower chuck and a surface of the upper chuck, respectively.

21-24. (canceled)
